(19) United States
(12) Patent Application Publication
(10) Pub. No.: US 2003/0070124 A1
(43) Pub. Date: Apr. 10, 2003

(54) Serial communication apparatus having software function to correct error

(75) Inventor: Toru Koike, Komae (JP)

Correspondence Address: STAAS & HALSEY LLP, 700 11TH STREET, NW, SUITE 500, WASHINGTON, DC, 20001, US

(73) Assignee: FUJITSU LIMITED, Kawasaki (JP)

(21) Appl. No.: 10/102,740

(22) Filed: Mar. 22, 2002

(30) Foreign Application Priority Data
Oct. 5, 2001 (JP) 2001-309933

(51) Int. Cl. G01R 31/28; G06F 11/00

(52) U.S. Cl. 714/712; 714/738

(57) ABSTRACT

An apparatus for serial communication includes a communication function block unit which transmits a serial communication output, a logical operation unit which performs an logical operation on the serial communication output, a register which stores settings therein indicative of an error detection condition and an error correction condition, and an error correction unit which controls said logical operation unit according to the error correction condition in such a manner as to correct an error of the serial communication output upon detecting the error according to the error detection condition.

### BACKGROUND OF THE INVENTION

1. Field of the Invention

The present invention generally relates to circuits which correct faults in communication apparatuses, and particularly relates to a circuit which corrects faults that are found in a serial communication function apparatus at the development stage thereof.

2. Description of the Related Art

When serial communication function apparatuses for use in USB or the like are developed, hardware is designed, evaluated, and tested. If faults (errors of the like) are found, the hardware design is changed, followed by further evaluation and testing. As the development of apparatus comes close to the final stage, it would take time to correct faults if hardware design is changed, evaluated, and tested when faults are found in communication functions. Especially when the time for manufacturing is approaching, correction must be done in as short a time as possible.

In related-art serial communication function apparatuses, when implemented hardware of communication protocols has faults, the hardware design is modified to correct the faults. When the hardware of serial communication functions is changed, design data need to be evaluated and tested again, resulting in cost increases and a delay in schedule.

Accordingly, there is a need for a circuit which can correct faults of a serial communication function apparatus at its development stage effectively in a short time.

### SUMMARY OF THE INVENTION

It is a general object of the present invention to provide a serial communication apparatus that substantially obviates one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by a serial communication apparatus particularly pointed out in the specification in such full, clear, concise, and exact terms as to enable a person having ordinary skill in the art to practice the invention.

To achieve these and other advantages and in accordance with the purpose of the invention, as embodied and broadly described herein, an apparatus for serial communication according to the present invention includes a communication function block unit which transmits a serial communication output, a logical operation unit which performs a logical operation on the serial communication output, a register which stores settings therein indicative of an error detection condition and an error correction condition, and an error correction unit which controls said logical operation unit according to the error correction condition in such a manner as to correct an error of the serial communication output upon detecting the error according to the error detection condition.

The serial communication function apparatus according to the present invention sets bit patterns, error flags, etc., as the error detection condition in the register for the purpose of detecting communication faults when the communication faults are found in the communication function block unit. Further, the serial communication function apparatus sets the error correction condition in the register such as pulse signal patterns and signal processing conditions (AND, OR, and NOR), etc., for correcting the faults. According to these settings, the error correction block monitors serial communication data of the communication function block unit, and applies logical processing through the logical operation unit at the timing at which the fault occurs, thereby outputting a fault-free serial communication output.

In this manner, the serial communication function apparatus according to the present invention sets the contents of the register according to faults if the faults occur in the serial communication functions, thereby correcting the faults of serial communication functions through use of software.

Other objects and further features of the present invention will be apparent from the following detailed description when read in conjunction with the accompanying drawings.

### BRIEF DESCRIPTION OF THE DRAWINGS

FIG. 1 is a block diagram showing an example of a serial communication function apparatus according to the present invention;

FIG. 2 is a drawing showing an example of a selection-circuit control register;

FIG. 3 is a drawing showing an example of a received-data setting register;

FIG. 4 is a drawing showing an example of a pulse string transmission condition setting register;

FIG. 5 is a drawing showing an example of an error flag setting register;

FIG. 6 is a drawing showing an example of a bit pattern setting register;

FIG. 7 is a drawing showing an example of a detection condition setting register;

FIG. 8 is a drawing showing an example of a pulse string setting register;

FIGS. 9A and 9B are timing charts showing operations of the serial communication function apparatus according to the present invention;

FIG. 10 is a drawing showing an example of register settings for the detection and correction of stuffing error;

FIG. 11 is a timing chart that shows another example of an operation of the serial communication function apparatus according to the present invention;

FIG. 12 is a drawing showing an example of register settings for a test operation that generates an arbitration error; and

FIG. 13 is a circuit diagram showing a schematic configuration of an error correction block.

### DESCRIPTION OF THE PREFERRED EMBODIMENTS

In the following, embodiments of the present invention will be described with reference to the accompanying drawings.

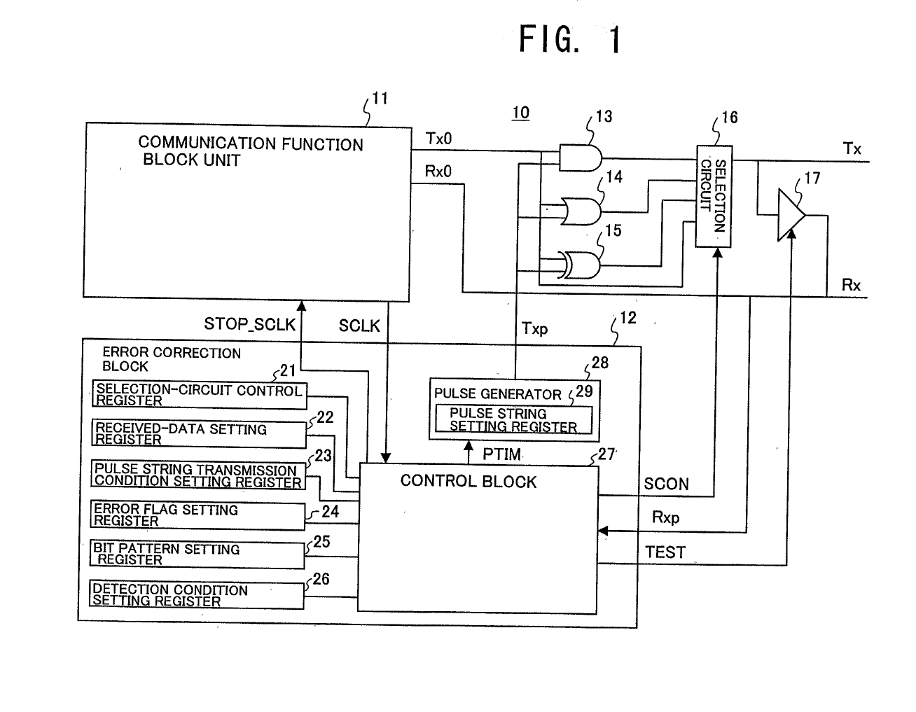

FIG. 1 is a block diagram showing an example of a serial communication function apparatus according to the present invention.

The serial communication function apparatus 10 of FIG. 1 includes a communication function block unit 11, an error correction block 12, an AND circuit 13, an OR circuit 14, an XOR circuit 15, a selection circuit 16, and a tri-state buffer 17. The error correction block 12 includes a selection-circuit control register 21, a received-data setting register 22, a pulse string transmission condition setting register 23, an error flag setting register 24, a bit pattern setting register 25, a detection condition setting register 26, a control block 27, and a pulse generator 28. The pulse generator 28 includes a pulse string setting register 29.

The communication function block unit 11 corresponds to a conventional serial communication function apparatus. The communication function block unit 11 transmits a serial communication output Tx0 and receives a serial communication input Rx0 according to predetermined protocols, thereby performing serial communication. The error correction block 12 detects the fault of serial communication based on the error conditions set in registers, thereby transmitting a pulse string Txp and controlling a transmission clock SCLK and the like according to data settings in predetermined registers. The AND circuit 13 performs an AND operation between the output Tx0 of the communication function block unit 11 and the output Txp of the error correction block 12. The OR circuit 14 performs an OR operation between the output Tx0 of the communication function block unit 11 and the output Txp of the error correction block 12. The XOR circuit 15 obtains an Exclusive-OR between the output Tx0 of the communication function block unit 11 and the output Txp of the error correction block 12.

Based on a selection control signal SCON supplied from the error correction block 12, the selection circuit 16 selects one of the output of the AND circuit 13, the output of the OR circuit 14, and the output of the XOR circuit 15, and outputs the selected one as a serial communication output Tx. The tri-state buffer 17 will supply the serial communication output Tx to the communication function block unit 11 as a serial communication input Rx when a test mode signal TEST from the error correction block 12 is asserted. The tri-state buffer 17 is provided for the purpose of testing the communication function block unit 11 by supplying a test-purpose signal to the communication function block unit 11. The test-purpose signal is generated by processing the serial communication output Tx0 from the communication function block unit 11 under the control of the error correction block 12.

In the error correction block 12, the pulse generator 28 outputs the pulse string Txp according to data settings of the pulse string setting register 29. The selection-circuit control register 21 stores therein data for controlling the selection control signal SCON supplied to the selection circuit 16, a clock suspension control signal STOP_SCLK for controlling the transmission clock SCLK, the test mode signal TEST for controlling the tri-state buffer 17. The received-data setting register 22 stores therein bit patterns of received data that should be detected. These bit patterns are defined by the unit of one byte. The pulse string transmission condition setting register 23 stores therein the number of bits that should be corrected in the serial communication output Tx0 of the communication function block unit 11. The error flag setting register 24 stores therein error flags indicative of whether error detection is performed with respect to respective types of errors. The bit pattern setting register 25 stores bit patterns that should be detected as errors. These bit patterns are set by the unit of one bit. The detection condition setting register 26 stores various combinations of conditions for detecting faults (errors) where these conditions are stored in the registers described above.

The control block 27 receives the serial data Rxp (which is identical Rx), and compares the received serial data with the data settings and error condition settings of the registers. Based on this comparison, the control block 27 controls the output timing of the pulse generator 28 by use of a pulse timing signal PTIM, and attends to further control such as selection control by the selection circuit 16 and the control of the clock suspension control signal STOP_SCLK for suspending the transmission clock SCLK.

The serial communication function apparatus 10 according to the present invention sets bit patterns, error flags, etc., in the relevant registers of the error correction block 12 for the purpose of detecting communication faults when the communication faults are found to be occurring in the communication function block unit 11. Further, the serial communication function apparatus 10 makes settings to pulse signal patterns and signal processing conditions (AND, OR, and NOR), etc., for correcting the faults. According to these settings, the error correction block 12 monitors serial communication data of the communication function block unit 11, and outputs the selection control signal SCON and the correction-purpose pulse Txp from the pulse generator 28 in accordance with the timing at which the faults occur. Based on this pulse-generator output Txp and the selection control signal SCON, the communication output Tx0 of the communication function block unit 11 is subjected to logic processing, thereby providing a fault-free serial communication output Tx to the serial data bus. While this is done, the clock suspension control signal STOP_SCLK is supplied to the communication function block unit 11, thereby properly controlling the output timing of the communication function block unit 11.

In this manner, the serial communication function apparatus 10 according to the present invention sets the contents of the registers according to faults if the faults occur in the serial communication functions, thereby correcting the faults of serial communication functions through use of software.

In the following, settings of each register will be described in detail.

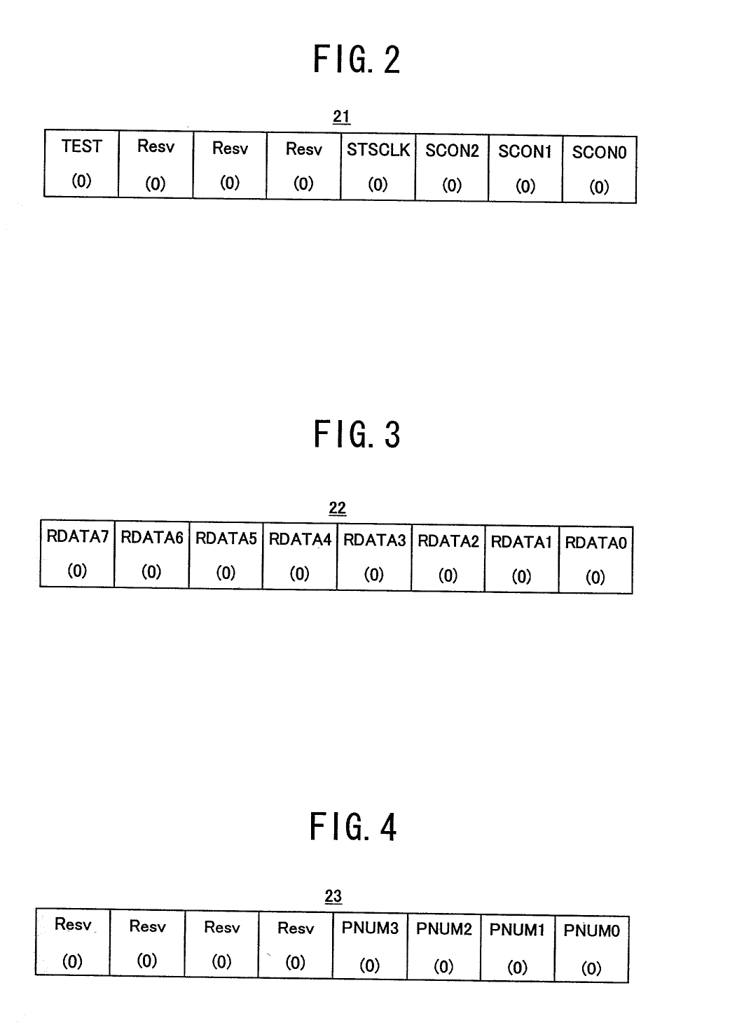

FIG. 2 is a drawing showing an example of the selection-circuit control register 21.

In this example, the selection-circuit control register 21 is an 8-bit register, and stores therein data for controlling the selection control signal SCON supplied to the selection circuit 16 and the transmission clock SCLK.

SCON0 through SCON2 are bits that control the selection operation of the selection circuit 16, and choose a logic operation that is to be performed on the serial communication output Tx0 of the communication function block unit 11. The settings of SCON0 through SCON2 are related to the logic operations as follows, for example.

If (SCON2, SCON1, SCON0)=(0, 0, 0), then Tx=Tx0;

If (SCON2, SCON1, SCON0)=(0, 0, 1), then Tx=(Tx0 AND Txp);

If (SCON2, SCON1, SCON0)=(0, 1, 0), then Tx=(Tx0 OR Txp); and

If (SCON2, SCON1, SCON0)=(1, 0, 0), then Tx=(Tx0 EXOR Txp).

TEST is a bit for switching between the normal mode and the test mode, and the setting thereof controls the test mode signal TEST for controlling the tri-state buffer 17. If TEST is 0, the normal operation mode is indicated. If TEST is 1, the test mode (Rx=Tx) is indicated. That is, if TEST is 1, the tri-state buffer 17 is driven and the serial communication output Tx is fed back as the serial communication input Rx.

STSCLK is a bit for controlling whether the transmission clock SCLK is suspended, and the setting thereof controls the clock suspension control signal STOP_SCLK. If STSCLK is 0, the transmission clock SCLK is not suspended even in the case of detection of predetermined error. If STSCLK is 1, the transmission clock SCLK will be suspended in response to the detection of the predetermined error.

Bits other than those described above (Resv in FIG. 2) are unused at present, and may be used for the expansion of functions in the future.

FIG. 3 is a drawing showing an example of the received-data setting register 22.

In this example, the received-data setting register 22 is an 8-bit register, and stores therein a bit pattern of received data that should be detected as error where this bit pattern is defined by the unit of one byte. If the bits RDATA0 through RDATA7 are “AA”, for example, an error will be detected when the bit pattern “10101010” appears in the received data Rx.

FIG. 4 is a drawing showing an example of the pulse string transmission condition setting register 23.

In this example, the pulse string transmission condition setting register 23 is an 8-bit register, and stores therein the number of bits that should be corrected in the serial communication output Tx0 supplied from the communication function block unit 11. In the figure, 4 bits of PNUM0 through PNUM3 specify the number of bits within the range between 0 and 15. If the 4 bits of PNUM0 through PNUM3 specifies “3”, for example, the pulse generator 28 generates pulses for three clocks as the pulse string Txp, thereby making correction for three clocks to the communication output Tx0 of the communication function block unit 11.

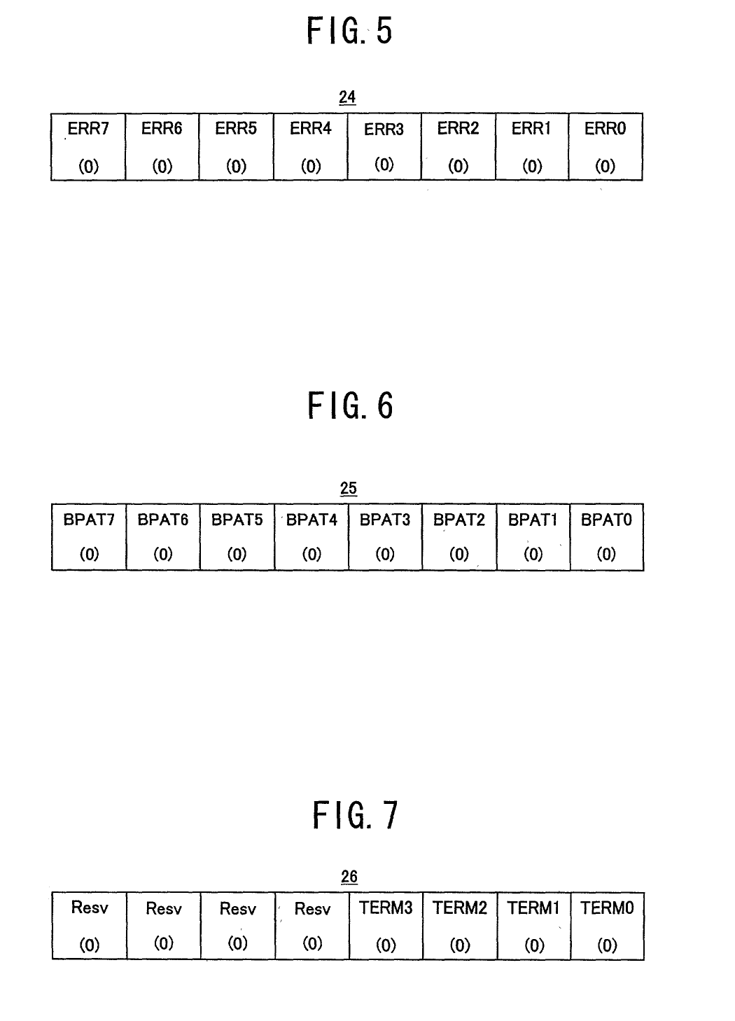

FIG. 5 is a drawing showing an example of the error flag setting register 24.

In this example, the error flag setting register 24 is an 8-bit register, and stores therein error flags indicative of whether error detection is performed with respect to the respective types of errors. ERR0 through ERR7 are assigned to 8 respective types of errors. If ERR2 corresponds to a stuffing error, for example, the setting of “1” to the flag ERR2 makes it possible to detect a stuffing error as it occurs. If ERR2 is set to 0, a stuffing error will be ignored when it occurs.

FIG. 6 is a drawing showing an example of the bit pattern setting register 25.

In this example, the bit pattern setting register 25 is an 8-bit register, and stores therein a bit pattern of received data that should be detected as error where this bit pattern is defined bit-wise. If bits BPAT0 through BPAT7 are “10101010”, for example, an error will be detected when this bit pattern appears in the received data Rx. The bit pattern setting register 25 specifies an error pattern on a bit-wise basis, whereas the received-data setting register 22 specifies an error pattern on a byte-wise basis. Despite this, there is no functional difference in effect. There are merits, however, in that the provision of the received-data setting register 22 and the bit pattern setting register 25 makes it possible to cope with two different error patterns, and, also, these two registers may be combined to detect a 16-bit error pattern. The bit pattern setting register 25 does not have to be a single register, and may be provided as many as desired to cope with a plurality of error patterns.

FIG. 7 is a drawing showing an example of the detection condition setting register 26.

In this example, the detection condition setting register 26 is an 8-bit register, and stores therein the combination of conditions that are stored in the registers described above for the purpose of using the combination of conditions to detect faults.

TERM0 through TERM3 are bits for controlling the error detection operation of the control block 27. The settings of these bits select the combination of error detection conditions stored in the respective registers. The settings of TERM0 through TERM3 are related to logical operations as follows, for example.

If (TERM3, TERM2, TERM1, TERM0)=(0, 0, 0, 0), then no error detection;

If (TERM3, TERM2, TERM1, TERM0)=(0, 0, 0, 1), then error conditions of respective registers are logically ANDed to detect an error;

If (TERM3, TERM2, TERM1, TERM0)=(0, 0, 1, 0), then error conditions of respective registers are logically ORed to detect an error;

If (TERM3, TERM2, TERM1, TERM0)=(0, 1, 0, 0), then error condition of the received-data setting register 22 and error condition of the bit pattern setting register 25 are logically ANDed to detect an error;

If (TERM3, TERM2, TERM1, TERM0)=(1, 0, 0, 0), then error condition of the received-data setting register 22 and error condition of the bit pattern setting register 25 are logically ORed to detect an error; and

Other combinations are prohibited.

Detecting errors by combining various error conditions of respective registers makes it possible to cope with any given one of the errors defined in the combination, and, also, makes it possible to attend to correction only when the defined errors occur simultaneously. Further, detection based on the OR operation or AND operation between the received-data setting register 22 and the bit pattern setting register 25 allows two different error patterns to be taken care of, and further allows the two registers to be combined to detect a 16-bit error pattern.

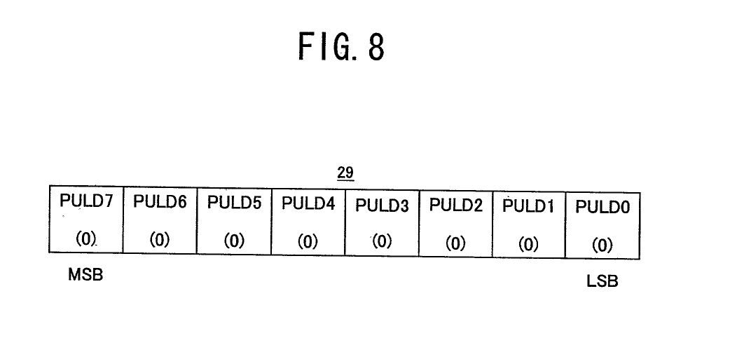

FIG. 8 is a drawing showing an example of the pulse string setting register 29.

In this example, the pulse string setting register 29 is an 8-bit register, and stores therein a bit pattern that the pulse generator 28 outputs as the pulse string Txp. If a bit pattern of “10100000” is set to PULD0 through PULD7, for example, the pulse generator 28 will serially output this bit pattern as the pulse string Txp. Here, the serial output is output with the least significant bit first.

The pulse string setting register 29 does not have to be single register, but may be provided as many as desired to cope with a plurality of different errors. If the pulse string setting registers 29 are provided for respective errors, pulse trans Txp that are suitable for respective types of errors can be output for the purpose of respective error corrections.

In the following, the operation of the serial communication function apparatus 10 will be described in detail with reference to examples of specific faults.

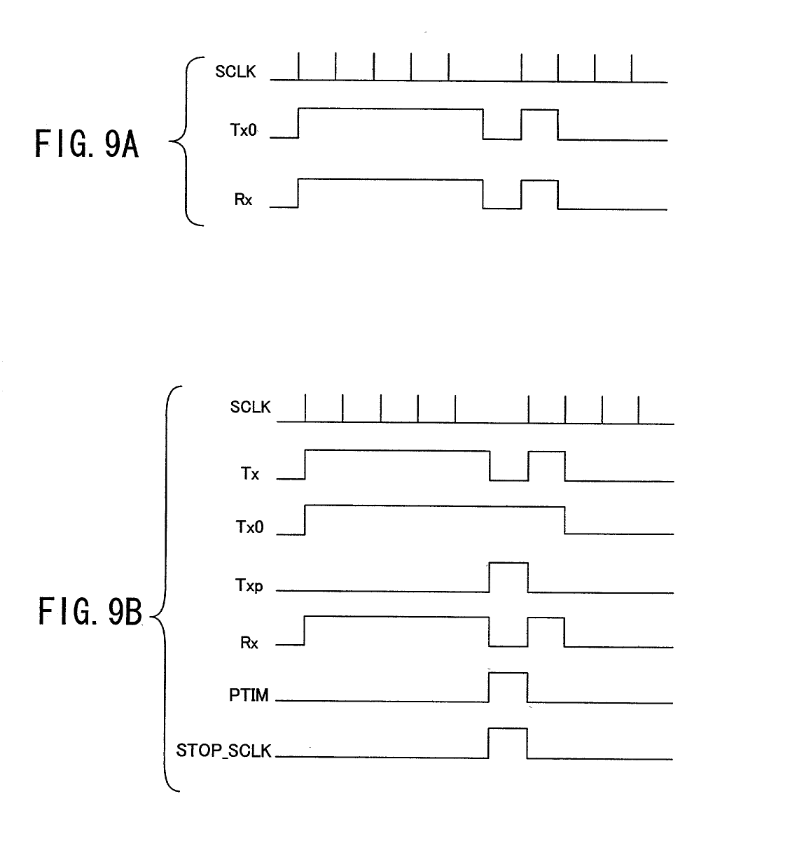

FIGS. 9A and 9B are timing charts showing operations of the serial communication function apparatus 10 according to the present invention. FIG. 9A shows timing with respect to a case in which the communication function block unit 11 properly operates, and FIG. 9B shows timing with respect to a case in which the communication function block unit 11 has a fault in the stuffing function.

FIGS. 9A and 9B show the communication clock SCLK, the serial communication output Tx to the bus, the output Tx0 of the communication function block unit 11, the output Txp of the pulse generator 28, the serial communication input Rx from the bus, the pulse timing signal PTIM indicative of the output timing of the pulse generator 28, and the clock suspension control signal STOP_SCLK for suspending the communication clock.

As shown in FIG. 9A, the output Tx0 of the communication function block unit 11 is comprised of five consecutive HIGH bits and one following LOW bit if the stuffing function of the communication function block unit 11 is properly operating. “Stuffing”, which is a rule defined by communication protocols, requires that the transmission signal always have one LOW bit after five consecutive HIGH bits, for example, even if the contents of the transmission data are all HIGH for a large number of consecutive bits. Accordingly, even if data “11111111” is to be transmitted, the actual transmission signal must be “111110111” when it is transmitted.

In FIG. 9A, the serial communication input Rx is the same as the output Tx0. This is because the serial communication bus is a two-way bus, in which the transmission of the output Tx0 results in the same signal being received at the receiver end with a slight analog delay.

FIG. 9B shows a case where fault is present in the stuffing function of the communication function block unit 11. Because of this fault, the output Tx0 of the communication function block unit 11 continues to be HIGH even after five consecutive HIGH bits. The serial communication function apparatus 10 according to the present invention uses the functions of the error correction block 12 and the like to correct the stuffing error. In the following, correction of errors will be described in detail.

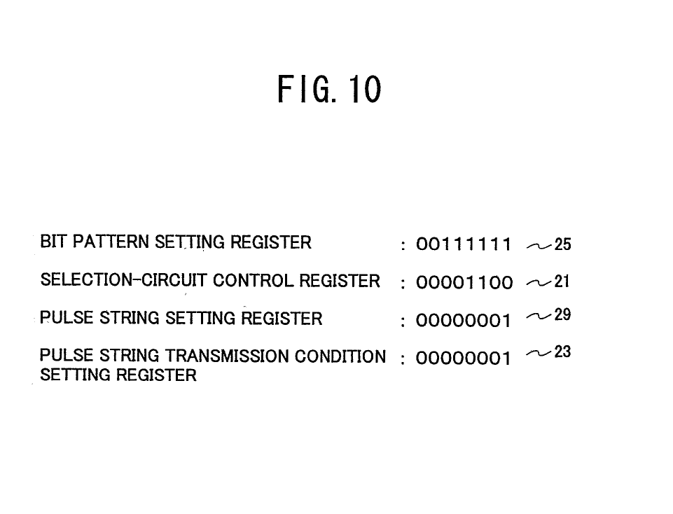

FIG. 10 is a drawing showing an example of register settings for the detection and correction of stuffing error.

As shown in FIG. 10, a bit pattern comprised of 6 consecutive HIGH bits is detected by setting “00111111” in the bit pattern setting register 25. In the selection-circuit control register 21, an Exclusive-OR operation Tx=(Tx0 EXOR Txp) is chosen by setting (SCON2, SCON1, SCON0) to (1, 0, 0) (see FIG. 2). Further, STSCLK is set to 1 so as to suspend the transmission clock SCLK upon detection of a predetermined error.

The pulse string setting register 29 is set to “00000001” so as to use a single HIGH pulse as a pulse string Txp transmitted from the pulse string setting register 29. In the pulse string transmission condition setting register 23, the 4 bits PNUM3 through PNUM0 are set to (0, 0, 0, 1), so that the pulse generator 28 generates a pulse signal for the duration of one clock cycle as the pulse string Txp.

With reference to FIG. 9B again, the error correction block 12 detects 6th HIGH bit in the communication input Rx at the position where stuffing should occur (i.e., the bit position after consecutive HIGH bits), thereby outputting the pulse timing signal PTIM to the pulse generator 28. In response to the pulse timing signal PTIM, the pulse generator 28 outputs one bit that is HIGH as the pulse string Txp. In this case, an Exclusive-OR has been selected as the logical operation, so that an EXOR operation is performed between the pulse string Txp and the communication output Tx0 of the communication function block unit 11, thereby turning the sixth bit into LOW as shown in the serial communication output Tx.

At the timing of this bit conversion from HIGH to LOW, the error correction block 12 sets the clock suspension control signal STOP_SCLK to HIGH so as to suspend the transmission clock SCLK. This is done because the communication function block unit 11 is transmitting the communication signal without inserting a stuffing bit in the communication data contents. It is necessary to insert the stuffing bit through an Exclusive-OR operation after halting the data transmission through suspension of the transmission clock SCLK. If the Exclusive-OR operation is performed without suspending the transmission clock SCLK, the data contents will be lost.

After inserting one bit as a stuffing bit, the clock suspension control signal STOP_SCLK is negated to resume the transmission clock SCLK, so that the operation returns to a normal and routine operation. In this manner, the stuffing error that exists in the output Tx0 of the communication function block unit 11 is corrected, and the serial communication output Tx in which the stuffing bit is correctly inserted is output to the bus as shown in FIG. 9B.

In the serial communication function apparatus 10 according to the present invention described above, the contents of each resister are suitably set such as to correct the error of stuffing bits through the operation of software. In the embodiment described above, the stuffing error is detected by the bit settings of the bit pattern setting register 25. Alternatively, a byte pattern may be set in the received-data setting register 22 to detect the error, or a corresponding bit belonging to the stuffing error is set in the error flag setting register 24 to detect the error.

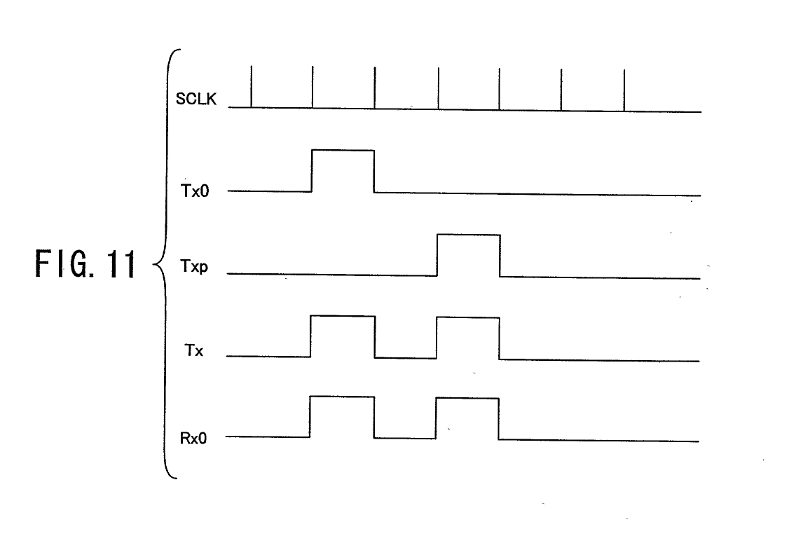

FIG. 11 is a timing chart that shows another example of an operation of the serial communication function apparatus 10 according to the present invention. FIG. 11 shows an example in which an abnormal pulse is generated by use of a test function, and the generated abnormal pulse is supplied to the communication function block unit 11.

As was described in connection with FIG. 1, the tri-state buffer 17 is provided in the serial communication function apparatus 10 of the present invention. The serial communication output Tx0 of the communication function block unit 11 is processed under the control of the error correction block 12 so as to generate a test signal, which is then supplied to the communication function block unit 11 for the purpose of testing the communication function block unit 11. The test signal may be an abnormal pulse that cannot be generated under normal circumstances. It is generally necessary to insure that the operation of the communication function block unit 11 does not fault even when receiving such an abnormal pulse.

The example of FIG. 11 shows a case in which an arbitration error is simulated. The arbitration error is the error that occurs when signal levels differ between the communication output-Tx0 and the communication input Rx0. Generally, the communication output Tx0 and the communication input Rx0 are connected via the bus, and thus maintain the same signal level. If a signal line is severed, or if but arbitration fails, for example, signal levels differ, resulting in the arbitration error.

In FIG. 11, Tx0 denotes the serial communication output of the communication function block unit 11, and Txp represents the output of the pulse generator 28 of the error correction block 12. Tx is the serial communication output that is obtained after the logic operation between Tx0 and Txp, and Rx0 is the serial communication input that is supplied to the communication function block unit 11. The communication function block unit 11 outputs the serial communication output Tx0 as a normal pulse. Upon detecting the bit pattern “010,” the error correction block 12 supplies one-bit pulse Txp from the pulse generator 28. In this case, a logical sum has been selected as the logical operation, so that a logical sum is performed between the output pulse Txp of the pulse generator 28 and the output Tx0 of the communication function block unit 11, thereby generating the pulse signal Tx as shown in FIG. 11.

Since a test mode is selected, the serial communication output Tx is fed back through the tri-state buffer 17 so as to be supplied as the serial communication input Rx. In this case, therefore, the communication output Tx0 output from the communication function block unit 11 and the serial communication input Rx0 input into the communication function block unit 11 have conflicting signal levels, which simulate the condition of arbitration error.

In this manner, use of the test function of the serial communication function apparatus 10 of the present invention makes it possible to create conditions that simulate an arbitration error and to check to see if the communication function block unit 11 properly operates.

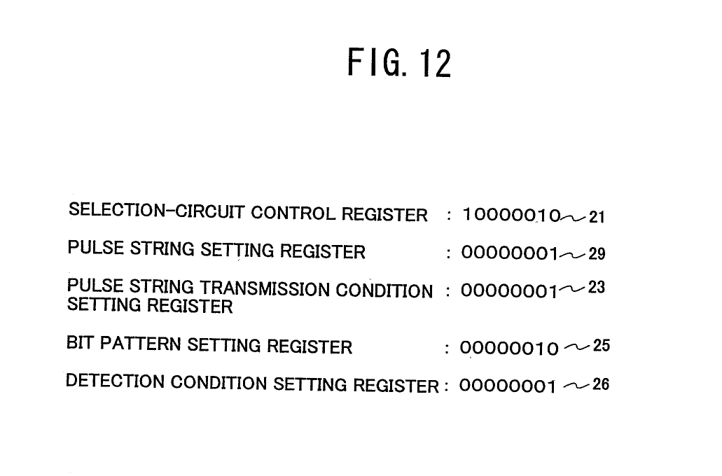

FIG. 12 is a drawing showing an example of register settings for the test operation that generates an arbitration error.

As shown in FIG. 12, the bit pattern “010” is detected by setting “00000010” in the bit pattern setting register 25. In the selection-circuit control register 21, (SCON2, SCON1, SCON0) are set to (0, 1, 0) so as to select an OR operation Tx=(Tx0 OR Txp) (see FIG. 2). Further, the test mode that uses the tri-state buffer 17 is chosen by setting TEST to 1.

Further, the pulse string setting register 29 has the contents thereof set to “00000001”, thereby selecting a single HIGH pulse to serve as the pulse string Txp transmitted from the pulse string setting register 29. In the pulse string transmission condition setting register 23, the 4 bits PNUM3 through PNUM0 are set to (0, 0, 0, 1), so that the pulse generator 28 generates a pulse signal for the duration of one clock cycle as the pulse string Txp. Further, the detection condition setting register 26 has the settings thereof that detect errors through a logical AND between the conditions of respective registers.

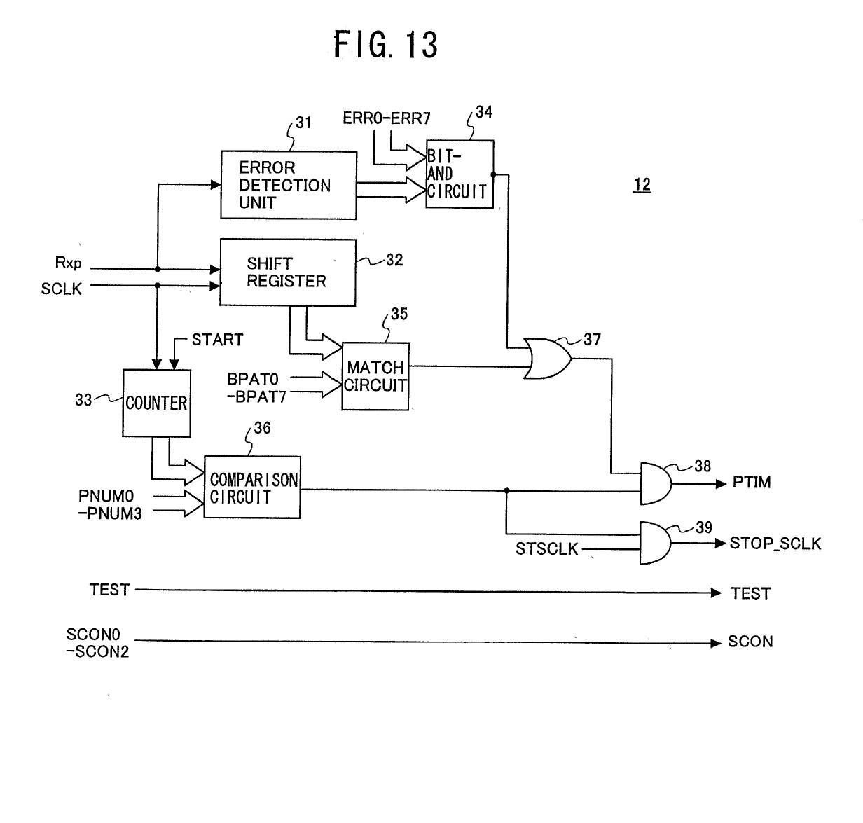

FIG. 13 is a circuit diagram showing a schematic configuration of the error correction block 12.

The error correction block 12 of FIG. 13 includes an error detection unit 31, a shift register 32, a counter 33, a bit-AND circuit 34, a match circuit 35, a comparison circuit 36, an OR circuit 37, and AND circuits 38 and 39. FIG. 13 shows a partial configuration relating only to registers that are of primary importance to the operation of error detection and correction.

The error detection unit 31 receives the communication input Rxp supplied to the error correction block 12, and detects presence/absence of errors with respect to a plurality of predetermined error types, followed by supplying the detection results to the bit-AND circuit 34 as signals corresponding to the respective errors. The predetermined error types mentioned above are those which are assigned to the respective flags of the error flag setting register 24. The bit-AND circuit 34 carries out an AND operation on a bit-by-bit basis between the detection results supplied from the error detection unit 31 and the error flags ERR0 through ERR7 supplied from the error flag setting register 24. The bit-AND circuit 34 sets the output thereof to HIGH if there is at least one bit for which an error is present and an error flag is 1.

The shift register 32 receives the communication input-Rxp supplied to the error correction block 12, and performs shift operations in synchronization with the communication clock SCLK so as to successively store the received serial signal in the shift register. The shift register 32 has an 8-bit configuration, for example, the contents of which are supplied to the match circuit 35 as 8-bit parallel signals. The match circuit 35 receives BPAT0 through BPAT7 of the bit pattern setting register 25, and compares this bit pattern with the bit pattern supplied from the shift register 32. The match circuit 35 sets the output thereof to HIGH if these bit patterns match.

The OR circuit 37 carries out an OR operation between the output of the bit-AND circuit 34 and the output of the match circuit 35, thereby generating a signal that indicates the detection of error.

The counter 33 starts counting the clock pulses of the communication clock SCLK in response to a count-start signal START, which is for example the above-noted signal generated by the OR circuit 37 to indicate the error detection. The count is supplied to the comparison circuit 36 as a 4-bit signal, for example. The comparison circuit 36 receives PNUM0 through PNUM3 of the pulse string transmission condition setting register 23, and compares the received bits with the count supplied from the counter 33. If the count by the counter 33 is smaller than the number of bits that should be corrected as indicated by PNUM0 through PNUM3, the comparison circuit 36 sets the output thereof to HIGH.

The AND circuit 38 performs an AND operation between the signal indicative of the error detection generated by the OR circuit 37 and the output of the comparison circuit 36. Through this operation, HIGH pulses having as many bits as the number of error correction bits are output as the pulse timing signal PTIM only if an error is detected.

The AND circuit 39 performs an AND operation between the output of the comparison circuit 36 and the STSCLK bit of the selection-circuit control register 21. Through this operation, HIGH pulses having as many bits as the number of error correction bits are output as the clock suspension control signal STOP_SCLK if there are settings that indicate the suspension of the communication clock SCLK.

The TEST bit of the selection-circuit control register 21 that is supplied to the error correction block 12 will pass through and be output to the tri-state buffer 17 as a test mode signal TEST. The bits SCON0 through SCON2 of the selection-circuit control register 21 that are supplied to the error correction block 12 will pass through and be output as a selection-control signal SCON to the selection circuit 16.

Further, the present invention is not limited to these embodiments, but various variations and modifications may be made without departing from the scope of the present invention.

The present application is based on Japanese priority application No. 2001-309933 filed on Oct. 5, 2001, with the Japanese Patent Office, the entire contents of which are hereby incorporated by reference.

What is claimed is:

1. An apparatus for serial communication, comprising:
a communication function block unit which transmits a serial communication output;
a logical operation unit which performs an logical operation on the serial communication output;
a register which stores settings therein indicative of an error detection condition and an error correction condition; and
an error correction unit which controls said logical operation unit according to the error correction condition in such a manner as to correct an error of the serial communication output upon detecting the error according to the error detection condition.

2. The apparatus as claimed in claim 1, wherein said communication function block unit receives a serial communication input, said apparatus further comprising a circuit which is controlled by said error correction unit, and feeds back the serial communication output to said communication function block unit as the serial communication input after said logical operation unit performs the logical operation on the serial communication output.

3. The apparatus as claimed in claim 2, wherein said register stores the settings therein that are indicative of whether to feed back the serial communication output as the serial communication input through said circuit.

4. The apparatus as claimed in claim 1, wherein said error correction unit suspends supply of a transmission clock to said communication function block unit upon detecting the error of the serial communication output.

5. The apparatus as claimed in claim 4, wherein said register stores the settings therein that are indicative of whether to suspend the supply of a transmission clock to said communication function block unit.

6. The apparatus as claimed in claim 1, wherein said logical operation unit includes:
an AND circuit;
an OR circuit;
an Exclusive-OR circuit; and
a selector which selects one of the circuit.

7. The apparatus as claimed in claim 6, wherein said register stores the settings therein that control the selection made by said selector.

8. The apparatus as claimed in claim 1, where said error correction unit further includes a pulse generation circuit which generates a predetermined bit pattern comprised of a predetermined number of bits specified by the settings of said register.

9. An apparatus for serial communication, comprising:
a communication function block unit which has a functional error caused by a design fault;
a register which stores settings therein indicative of a first condition for detecting an error and a second condition for correcting an error; and
an error correction unit which monitors a serial communication output transmitted from said communication function block unit to detect an error of the serial communication output according the first condition, and corrects the error of the serial communication output according to the second condition, whereby said communication function block unit continues to operate without causing a system fault despite said functional error caused by the design fault.

10. The apparatus as claimed in claim 9, further comprising a circuit which is controlled by said error correction unit, and feeds back the serial communication output to said communication function block unit as an input thereto after the error is corrected.
